(19) United States
(12) Patent Application Publication
(10) Pub. No.: US 2015/0345046 A1
(43) Pub. Date: Dec. 3, 2015

(54) FILM-FORMING DEVICE

(71) Applicant: SHOWA DENKO K.K., Tokyo (JP)

(72) Inventors: Daisuke MUTO, Chichibu-shi, Saitama (JP); Yusuke KIMURA, Chichibu-shi, Saitama (JP); Tomoya UTASHIRO, Kawasaki, Kanagawa (JP); Seiichi TAKAHASHI, Midori-ku, Chiba (JP); Kenji MOMOSE, Chichibu-shi, Saitama (JP); Hisanori KURIBAYASHI, Kyoto-shi, Kyoto (JP); Naoki YASUDA, Kyoto-shi, Kyoto (JP)

(73) Assignee: SHOWA DENKO K.K., Tokyo (JP)

(21) Appl. No.: 14/655,827

(22) PCT Filed: Dec. 11, 2013
(86) PCT No.: PCT/JP2013/083253

§ 371 Date: Jun. 26, 2015

(30) Foreign Application Priority Data
Dec. 27, 2012 (JP) 2012-285151
Dec. 27, 2012 (JP) 2012-285152
Dec. 27, 2012 (JP) 2012-285153
Dec. 27, 2012 (JP) 2012-285155
Dec. 27, 2012 (JP) 2012-285161

(51) Int. Cl. C30B 25/08; C30B 25/10; C30B 29/36; C30B 25/20

(52) U.S. Cl. CPC C30B 25/08; C30B 25/20; C30B 25/10; C30B 29/36

(57) ABSTRACT

A CVD device equipped with a container chamber (100) having an interior space (100a), and containing a substrate in a manner such that the film formation surface thereof faces upward from the bottom side (fifth region (A5)) of the interior space (100a). Silane gas and propane gas are supplied to the interior space (100a). A stainless-steel ceiling (120) is provided on the top of the interior space (100a). The ceiling (120) is provided with first through third partition members (171-173) attached thereto which comprise stainless steel, are positioned so as to extend in the -Z-direction and transect the X-direction, and divide the top side of the interior space (100a) into first through fourth regions (A1-A4). The substrate positioned inside the interior space (100a) is heated to 1600° C. The first through third partition members (171-173) and the ceiling (120) are cooled to 300° C. or lower by a cooling mechanism.

### TECHNICAL FIELD

The present invention relates to a film-forming device that forms a film on a substrate.

### BACKGROUND ART

As compared to Si (silicon), SiC (silicon carbide) has excellent physical properties such that about threefold band gap, about tenfold dielectric breakdown field strength and about threefold thermal conductivity, and accordingly, application of SiC to a power device, a high-frequency device, a high-temperature operation device (hereinafter, these are collectively referred to as an SiC semiconductor device) and the like is expected.

The SiC semiconductor device is manufactured by use of, for example, an SiC epitaxial wafer that is an SiC single crystal thin film epitaxially grown on an SiC substrate made of an SiC single crystal. Usually, this kind of SiC epitaxial wafer is manufactured by the chemical vapor deposition method (hereinafter, referred to as the CVD method). In a film-forming device that carries out film formation by the CVD method, an SiC substrate is contained in a container chamber, then, as raw-material gases that are raw materials of the SiC single crystal thin film, a silicon-containing gas containing Si and a carbon-containing gas containing C are supplied to the container chamber, and the SiC substrate is heated to, for example, 1000° C. or higher, to thereby react the silicon-containing gas and the carbon-containing gas on the SiC substrate, and accordingly, the SiC single crystal thin film is deposited on the SiC substrate.

As a conventional art described in a gazette, there exists a film-forming device, in which a chamber as a film-forming chamber is configured with stainless-steel, and a hollow-cylindrical liner formed by coating carbon with SiC is arranged inside the chamber, to thereby form an SiC single crystal thin film on an SiC substrate inside the liner (refer to Patent Document 1).

Moreover, in a film-forming device that forms a film by the CVD method, reaction products generated by reaction of the raw-material gas in a reaction chamber sometimes adhere to an inner wall or the like of the reaction chamber. For example, in a CVD device that arranges a substrate in a reaction chamber so that a crystal growth surface thereof faces upward, of inner walls of the reaction chamber, reaction products can possibly adhere to a ceiling that is arranged above the substrate to face the crystal growth surface of the substrate. Then, if the reaction products adhered to the ceiling peel off in film-forming operation for some reason, clusters of the reaction products that have peeled off result in falling onto the crystal growth surface of the substrate.

As conventional arts described in gazettes, there exist a thin-film forming device that supplies a first gas flow in a sheet form substantially in parallel with a surface of a substrate provided in a sealing tub and introduces a second gas flow to the surface of the substrate from a direction perpendicular to the surface, to thereby maintain the second gas flow in a layered flow state in proximity to the surface of the substrate, in which a gas jetting member having many small holes for introducing the second gas flow is provided at a position facing the surface of the substrate, and many flow guard members arranged below the gas jetting member with intervals to one another so as to extend in parallel with an axial line of each small hole in the gas jetting member (refer to Patent Document 2 and Patent Document 3).

### CITATION LIST

### Patent Literature

Patent Document 1: Japanese Patent Application Laid-Open Publication No. 2011-195346
Patent Document 2: Japanese Patent Application Laid-Open Publication No. H5-345978
Patent Document 3: Japanese Patent Application Laid-Open Publication No. H5-175136

### SUMMARY OF INVENTION

### Technical Problem

However, in the case where a stainless steel member configured with stainless steel is exposed inside the container chamber, the stainless steel member becomes brittle due to a phenomenon in which carbonized deterioration is caused by a carburization gas containing carbon hydride, which is one of the raw-material gases, in some cases.

The present invention has as an object to suppress deterioration of the stainless steel member exposed inside the container chamber that contains the substrate.

### Solution to Problem

A film-forming device according to the present invention includes: a container chamber that includes an interior space to which a stainless steel member configured with a material containing stainless steel is exposed, and contains a substrate for forming an SiC film; a raw-material gas supply unit that supplies the interior space with a raw-material gas containing a first raw-material gas that contains Si and serves as a raw material of the SiC film and a second raw-material gas that contains C and serves as a raw material of the SiC film; a heating unit that heats the substrate contained in the interior space; and a cooling unit that cools a region of the stainless steel member, which is exposed to the interior space and positioned above the heating unit, to 300° C. or lower.

In such a film-forming device, the raw-material gas supply unit supplies the interior space with the raw-material gas along a first direction heading toward the substrate from a lateral side of the substrate, a blocking gas supply unit, which supplies the interior space with a blocking gas that suppresses upward movement of the raw-material gas along a second direction heading downward from above, is further included, and the stainless steel member is provided on an upper side in the interior space to extend in the second direction and to intersect the first direction, and includes a dividing member that divides the upper side in the interior space into a plurality of regions.

Moreover, the stainless steel member is provided above the substrate in the interior space, and further includes a ceiling member to which the dividing member is attached.

Further, the cooling unit indirectly cools the ceiling member via the dividing member by directly cooling the dividing member.

Still further, on the upper side of the interior space, the blocking gas supply unit supplies each of the plurality of regions, which is formed by dividing the interior space by the dividing member, with the blocking gas.

Moreover, the container chamber contains the substrate on a lower side of the interior space so that a film-formation surface faces upward.

Further, plural dividing members are provided, and the cooling unit cools the plural dividing members individually.

Still further, the SiC film formed on the substrate includes a 4H—SiC structure.

Then, the heating unit heats the substrate to a film-forming temperature selected from a range of 1500° C. to 1800° C.

### Advantageous Effects of Invention

According to the present invention, it is possible to suppress deterioration of the stainless steel member exposed inside the container chamber that contains the substrate.

### BRIEF DESCRIPTION OF DRAWINGS

FIG. 1 is an entire configuration diagram showing a CVD device to which an exemplary embodiment is applied;

FIG. 2 is a perspective view of a substrate onto which a film is laminated and a loading body on which the substrate is loaded, which are used in the CVD device;

FIG. 3 is a virtual cross-sectional view of a reaction container in the CVD device;

FIG. 4 is a IV-IV cross-sectional view in FIG. 3;

FIG. 5 is a V-V cross-sectional view in FIG. 3;

FIG. 6 is a diagram for illustrating a configuration of a first dividing member provided in a container chamber;

FIG. 7 is a diagram for illustrating various dimensions in the reaction container; and

FIG. 8 is a diagram schematically showing flows of a raw-material gas and a blocking gas in the reaction container.

### DESCRIPTION OF EMBODIMENTS

Hereinafter, an exemplary embodiment according to the present invention will be described in detail with reference to attached drawings.

### <Entire Configuration of CVD Device>

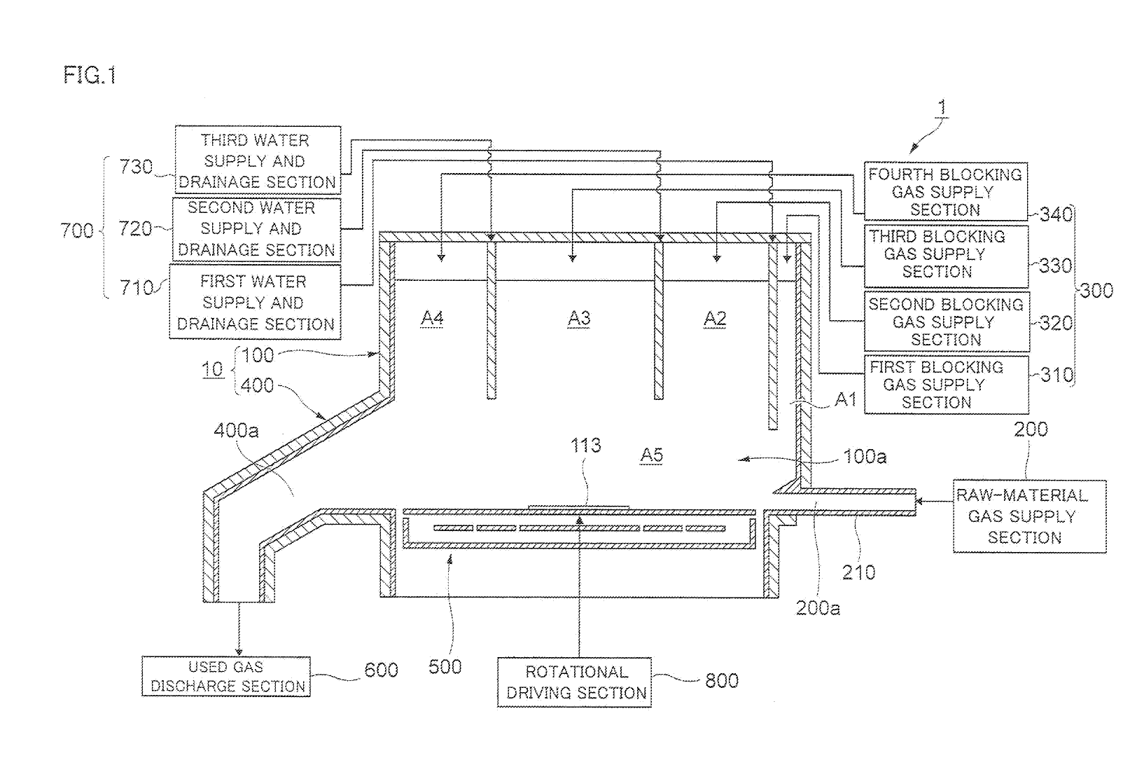

FIG. 1 is an entire configuration diagram of a CVD device 1 to which an exemplary embodiment is applied.

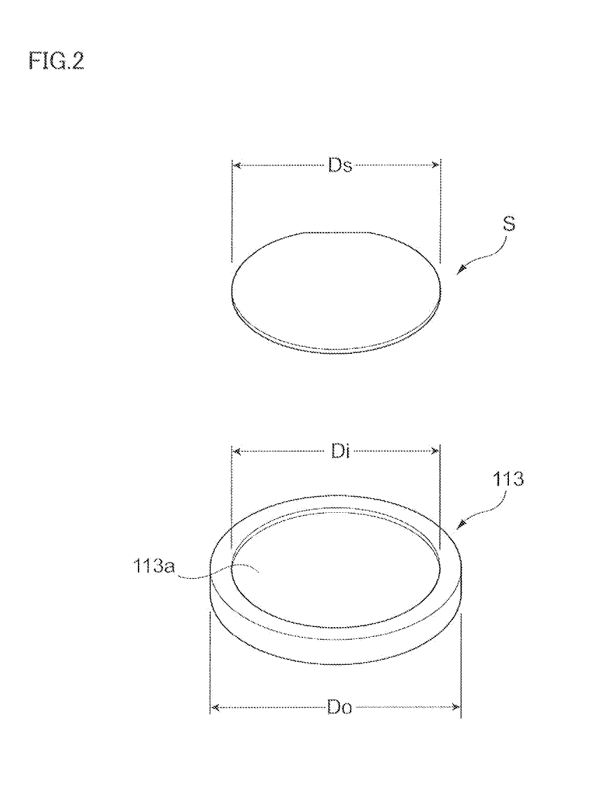

Moreover, FIG. 2 is a perspective view of a substrate S onto which a film is laminated and a loading body 113 on which the substrate S is loaded, which are used in the CVD device 1.

The CVD device 1 as an example of a film-forming device is used for producing an SiC epitaxial wafer in which a 4H—SiC film is epitaxially grown on the substrate S configured with SiC (silicon carbide) single crystals by a so-called thermal CVD method.

The CVD device 1 has a reaction container 10 including: a container chamber 100, in which vapor phase reaction for growing the film on the substrate S is performed, and which is provided with an interior space 100a for containing the substrate S loaded on the loading body 113; and a discharge duct 400, which is provided with a discharge space 400a communicated to the interior space 100a, for discharging gas inside the interior space 100a to the outside.

Moreover, in addition to the reaction container 10, the CVD device 1 further includes: a raw-material gas supply section 200 that supplies the interior space 100a of the container chamber 100 with a raw-material gas, which is a raw material for a film, via a supply space 200a provided in a supply duct 210; a blocking gas supply section 300 that supplies the interior space 100a of the container chamber 100 with a blocking gas for assisting in carrying the raw-material gas along the horizontal direction and blocking an upward movement of the raw-material gas; a heating mechanism 500 that heats the substrate S and surroundings thereof in the container chamber 100; a used gas discharge section 600 that discharges used gases (such as the raw-material gas (including a gas having been subjected to reaction), the blocking gas and the like) carried from the interior space 100a of the container chamber 100 to the outside via the discharge space 400a provided in the discharge duct 400; a cooling mechanism 700 that cools important sections (details will be described later) in the container chamber 100; and a rotational driving section 800 that rotates the substrate S via the loading body 113 in the container chamber 100. It should be noted that the used gas discharge section 600 is also used in reducing pressure in the interior space 100a via the discharge space 400a.

Here, the loading body 113 has a disk shape, and at a center portion of the top surface thereof, a recessed portion 113a for placing the substrate S is provided. The loading body 113 is configured with graphite (carbon). The graphite may be coated with SiC, TaC or the like.

Moreover, as the substrate S, of the SiC single crystal having many polytypes, the one with any polytype may be used; however, in a case where the film to be formed on the substrate S is configured with 4H-SiC, it is desirable to use 4H-SiC as the substrate S. Here, as an off angle imparted to a crystal growth surface of the substrate S, any off angle may be imparted; however, in terms of reduction of cost of producing the substrate S while ensuring step-flow growth of the SiC film, it is preferable to set the off angle of the order of 0.4° to 8°.

It should be noted that the substrate diameter Ds, which is the outer diameter of the substrate S, is able to be selected from various sizes, such as 2 inches, 3 inches, 4 inches, 6 inches or the like. At this time, the loading body inner diameter Di, which is the inner diameter of the recessed portion 113a in the loading body 113, is set slightly larger than the substrate diameter Ds, whereas, the loading body outer diameter Do, which is the outer diameter of the loading body 113, is set larger than the loading body inner diameter Di (Ds<Di<Do).

Moreover, as the raw-material gas to be supplied to the container chamber 100 by use of the raw-material gas supply section 200 as an example of a raw-material gas supply unit, it can be safely said that the gas is appropriately selected from gases capable of forming the SiC on the substrate S along the vapor phase reaction in the container chamber 100; however, usually, the silicon-containing gas that contains Si and the carbon-containing gas that contains C are used. It should be noted that, in this example, monosilane (SiH₄) gas and propane (C₃H₈) gas are used as the silicon-containing gas as an example of a first raw-material gas and the carbon-containing gas as an example of a second raw-material gas, respectively. Moreover, the raw-material gas of the exemplary embodiment contains hydrogen (H₂) gas as a carrier gas, in addition to the above-described monosilane gas and propane gas. It should be noted that the raw-material gas supply section 200 is able to supply the carrier gas only.

Further, as the blocking gas to be supplied to the container chamber 100 by use of the blocking gas supply section 300 as an example of a blocking gas supply unit, it is desirable to use a gas less reactive to the above-described raw-material gas (a gas that is inactive for the raw-material gas). In this example, as the blocking gas, hydrogen gas is used.

It should be noted that the SiC epitaxial film to be laminated on the substrate S is controlled to be a hole-conduction type (p-type) or an electron-conduction type (n-type), doping of a different element is performed when the SiC epitaxial film is laminated. Here, in the case where the SiC epitaxial film is controlled to be the p-type, it is desirable that the SiC epitaxial film is doped with aluminum (Al) as an acceptor. In this case, in the above-described raw-material gas, trimethyl aluminum (TMA) gas may further be contained. Moreover, in the case where the SiC epitaxial film is controlled to be the n-type, it is desirable that the SiC epitaxial film is doped with nitrogen as a donor. In this case, in the above-described raw-material gas or blocking gas, nitrogen (N₂) gas may further be contained.

### [Configuration of Reaction Container]

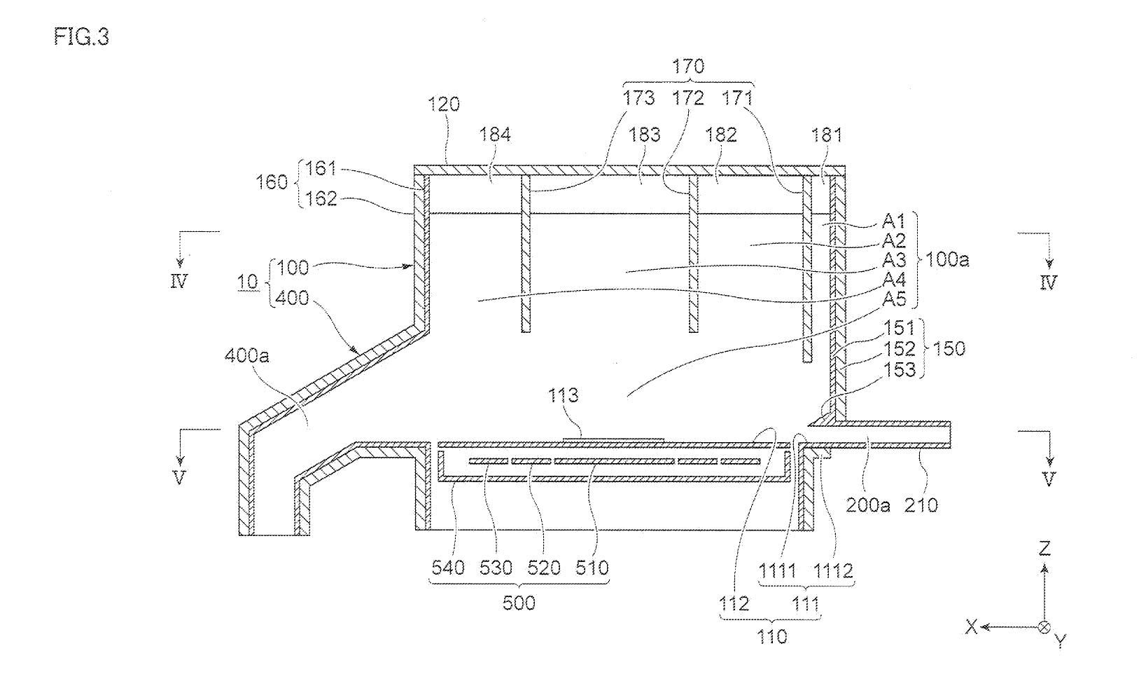

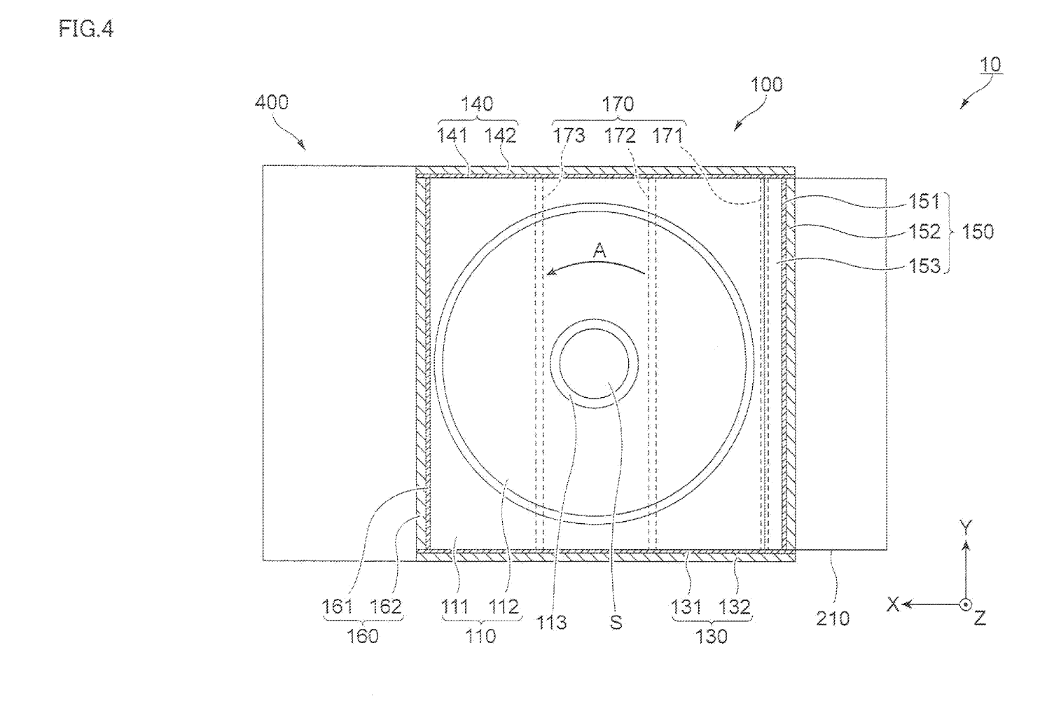

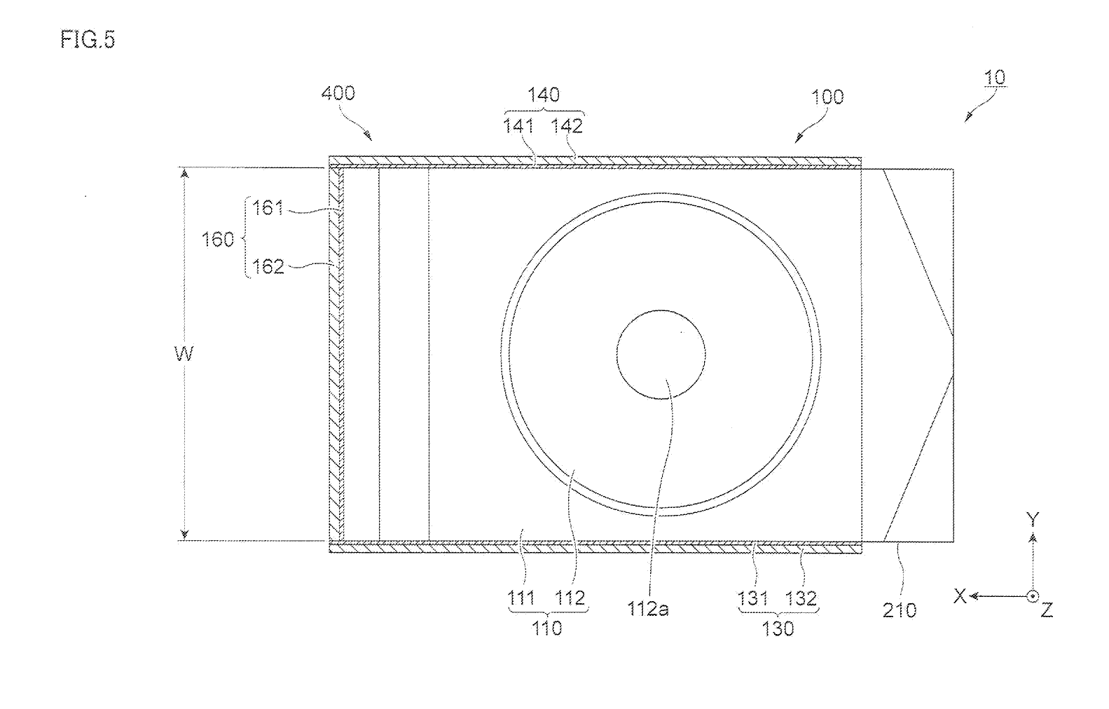

FIG. 3 is a virtual cross-sectional view of the reaction container 10 in the CVD device 1. Moreover, FIG. 4 is a IV-IV cross-sectional view in FIG. 3, and FIG. 5 is a V-V cross-sectional view in FIG. 3.

It should be noted that, in the following description, in FIG. 3, it is assumed that the direction heading from the right side toward the left side in the figure is an X-direction, the direction heading from the front side toward the rear side in the figure is a Y-direction, and the direction heading from the lower side toward the upper side in the figure is a Z-direction. Then, in this example, the Z-direction corresponds to the vertical direction, and the X-direction and the Y-direction correspond to the horizontal direction. Moreover, in the exemplary embodiment, the X-direction and the -Z-direction correspond to a first direction and a second direction, respectively.

The reaction container 10 includes: a floor section 110 provided along an XY plane on an upstream side in the Z-direction (a lower side) as viewed from the interior space 100a, on which the loading body 113 is arranged; a ceiling 120 provided along the XY plane on a downstream side in the Z-direction (an upper side) as viewed from the interior space 100a and facing the floor section 110; a first side wall 130 provided along an XZ plane on an upstream side in the Y-direction as viewed from the interior space 100a; a second side wall 140 provided along the XZ plane on a downstream side in the Y-direction as viewed from the interior space 100a and facing the first side wall 130; a third side wall 150 provided along a YZ plane on an upstream side in the X-direction as viewed from the interior space 100a; and a fourth side wall 160 provided along the YZ plane on a downstream side in the X-direction as viewed from the interior space 100a and facing the third side wall 150.

Here, at an end portion of the third side wall 150 on the upstream side in the Z-direction (the lower side), the supply duct 210 that connects the raw-material gas supply section 200 and the reaction container 10 (the container chamber 100) is attached, and inside the supply duct 210, the supply space 200a that communicates with the interior space 100a to supply the interior space 100a with the raw-material gas from the raw-material gas supply section 200 in a dispersed state is provided. Then, a communicating section of the supply space 200a and the interior space 100a, namely, an exit of the supply space 200a shows a rectangular shape with a side along the Y-direction as a long side and a side along the Z-direction as a short side.

Moreover, the floor section 110 is, after extending from the third side wall 150 along the X-direction, formed to be inclined obliquely downward along the X-direction and the -Z-direction in accordance with the discharge space 400a, and further, formed to be extended downward along the -Z-direction. On the other hand, the fourth side wall 160 is, after extending from the ceiling 120 along the -Z-direction, formed to be inclined obliquely downward along the X-direction and the -Z-direction in accordance with the discharge space 400a, and further, formed to be extended downward along the -Z-direction. Then, the first side wall 130 and the second side wall 140 are also extended in accordance with the discharge space 400a after the manner of the above-described floor section 110 and fourth side wall 160.

The floor section 110 is formed integrally with the first side wall 130, the second side wall 140 and the third side wall 150, and includes a fixing section 111 at a center portion of which a circular-shaped opening is formed, and a rotating table 112 that is arranged in the opening provided in the fixing section 111, to which the loading body 113 placing the substrate S is attached, and is rotationally driven in the direction of arrow A by the rotational driving section 800 (refer to FIG. 1).

The fixing section 111 constituting the floor section 110 includes a first inner wall 1111 that is arranged to be exposed to the interior space 100a and a first outer wall 1112 that is provided on a back side of the first inner wall 1111 as viewed from the interior space 100a. Here, the first inner wall 1111 is configured with TaC-coated graphite, which is formed by providing a coating layer of TaC (tantalum carbide) on a surface (on a side facing the interior space 100a) of a base material made of graphite (carbon), and the first outer wall 1112 is configured with stainless steel (in this example, SUS316, and the same applies hereafter). Then, in the floor section 110, by covering the first outer wall 1112 with the first inner wall 1111, the first outer wall 1112 is not exposed to the interior space 100a and the discharge space 400a.

Moreover, the rotating table 112 that constitutes the floor section 110 is also arranged to be exposed to the interior space 100a and is configured with the TaC-coated graphite, as same as the first inner wall 1111. Moreover, at a center portion of the top surface of the rotating table 112, a receiving section 112a (a recessed section) for attaching the loading body 113 is formed.

The ceiling 120 as an example of a ceiling member is configured with a plate material made of stainless steel, and stainless steel is exposed to the interior space 100a. Moreover, to the ceiling 120, a flow-adjusting section 170 configured with plural plate-like members to adjust the flow of various kinds of gases in the interior space 100a. It should be noted that details of the flow-adjusting section 170 will be described later.

The first side wall 130 includes a first inner wall 131 that is arranged to be exposed to the interior space 100a and a first outer wall 132 that is provided on a back side of the first inner wall 131 as viewed from the interior space 100a. Here, the first inner wall 131 is configured with the TaC-coated graphite, and the first outer wall 132 is configured with stainless steel. Then, in the first side wall 130, by covering the first outer wall 132 with the first inner wall 131, the first outer wall 132 is not exposed to the interior space 100a.

The second side wall 140 includes a second inner wall 141 that is arranged to be exposed to the interior space 100a and a second outer wall 142 that is provided on a back side of the second inner wall 141 as viewed from the interior space 100a. Here, the second inner wall 141 is configured with the TaC-coated graphite, and the second outer wall 142 is configured with stainless steel. Then, in the second side wall 140, by covering the second outer wall 142 with the second inner wall 141, the second outer wall 142 is not exposed to the interior space 100a.

The third side wall 150 includes a third inner wall 151 that is arranged to be exposed to the interior space 100a, a third outer wall 152 that is provided on a back side of the third inner wall 151 as viewed from the interior space 100a and a protruding member 153 arranged to protrude in the X-direction from a lower end side of the third inner wall 151. Here, the third inner wall 151 and the protruding member 153 are configured with the TaC-coated graphite, and the third outer wall 152 is configured with stainless steel. Then, in the third side wall 150, by covering the third outer wall 152 with the third inner wall 151, the third outer wall 152 is not exposed to the interior space 100a.

Moreover, the protruding member 153 provided in the third side wall 150 has an inclined surface that is inclined in the lower left direction in FIG. 3. Then, a tip end (an end portion on the downstream side in the X-direction) of the protruding member 153 extends to a position directly below a first dividing member 171, which will be described later.

The fourth side wall 160 includes a fourth inner wall 161 that is arranged to be exposed to the interior space 100a and a fourth outer wall 162 that is provided on a back side of the fourth inner wall 161 as viewed from the interior space 100a. Here, the fourth inner wall 161 is configured with the TaC-coated graphite, and the fourth outer wall 162 is configured with stainless steel. Then, in the fourth side wall 160, by covering the fourth outer wall 162 with the fourth inner wall 161, the fourth outer wall 162 is not exposed to the interior space 100a and the discharge space 400a.

It should be noted that the structures configured with the TaC-coated graphite in this example, such as the surfaces of the above-described first inner wall 131 to fourth inner wall 161 and the protruding member 153, are able to be configured with, for example, a carbon-based material or a metal material provided with a thermal insulation function and heat resistance for at least 600° C.

The flow-adjusting section 170 of the exemplary embodiment includes a first dividing member 171, a second dividing member 172 and a third dividing member 173, each of which is configured with a plate-like member made of stainless steel to divide the interior space 100a into plural regions. Here, in each of the first dividing member 171 to the third dividing member 173 as an example of a dividing member, an end portion on the upper side thereof is attached to the ceiling 120 and extends along the -Z-direction, and an end portion on the lower side thereof is positioned within the interior space 100a. Moreover, the first dividing member 171, the second dividing member 172 and the third dividing member 173 are arranged in this order along the X-direction. Then, the first dividing member 171 is arranged at a position facing the third side wall 150, the third dividing member 173 is arranged at a position facing the fourth side wall 160, and the second dividing member 172 is arranged at a position between the first dividing member 171 and the third dividing member 173. Here, in the exemplary embodiment, the ceiling 120 and the first dividing member 171 to the third dividing member 173 constituting the flow-adjusting section 170 have a function as the stainless steel member.

In the interior space 100a in the container chamber 100, the first dividing member 171 to the third dividing member 173 are arranged to avoid positions immediately above the loading body 113 put on the rotating table 112 of the floor section 110 and the substrate S loaded on the loading body 113. More specifically, in the exemplary embodiment, the loading body 113 is arranged at a portion between a position immediately below the second dividing member 172 and a position immediately below the third dividing member 173.

Then, in the exemplary embodiment, by attaching the first dividing member 171 to the third dividing member 173 to the interior space 100a, the interior space 100a is divided into 5 regions, more specifically, a first region A1, a second region A2, a third region A3, a fourth region A4 and a fifth region A5.

Of these, the first region A1 refers to a region, of the interior space 100a, surrounded by the ceiling 120, the first side wall 130, the second side wall 140, the third side wall 150 and the first dividing member 171.

Moreover, the second region A2 refers to a region, of the interior space 100a, surrounded by the ceiling 120, the first side wall 130, the second side wall 140, the first dividing member 171 and the second dividing member 172.

Further, the third region A3 refers to a region, of the interior space 100a, surrounded by the ceiling 120, the first side wall 130, the second side wall 140, the second dividing member 172 and the third dividing member 173.

Still further, the fourth region A4 refers to a region, of the interior space 100a, surrounded by the ceiling 120, the first side wall 130, the second side wall 140, the third dividing member 173 and the fourth side wall 160.

Then, the fifth region A5 refers to a region, of the interior space 100a, on the floor section 110 side that is not included in the above-described first region A1 to fourth region A4.

In the exemplary embodiment, on the downstream side of the fifth region A5 in the Z-direction (the upper side), the first region A1, the second region A2, the third region A3 and the fourth region A4 are arranged along the X-direction in this order. Then, the fifth region A5 is individually communicated with each of the first region A1 to the fourth region A4. Moreover, the fifth region A5 is communicated with the supply space 200a on the upstream side of the fifth region A5 in the X-direction, and is communicated with the discharge space 400a on the downstream side of the fifth region A5 in the X-direction.

It should be noted that, in the following description, as shown in FIG. 5, in the container chamber 100 (the interior space 100a) of the reaction container 10, the length from the first side wall 130 to the second side wall 140 in the Y-direction is referred to as an interior width W.

Then, the blocking gas supply section 300 of the exemplary embodiment includes, as shown in FIG. 1, via through holes (not shown) provided in the ceiling 120: a first blocking gas supply section 310 that supplies the inside of the first region A1 with a blocking gas (a first blocking gas) from above; a second blocking gas supply section 320 that supplies the inside of the second region A2 with a blocking gas (a second blocking gas) from above; a third blocking gas supply section 330 that supplies the inside of the third region A3 with a blocking gas (a third blocking gas) from above; and a fourth blocking gas supply section 340 that supplies the inside of the fourth region A4 with a blocking gas (a fourth blocking gas) from above. It should be noted that the blocking gas supply section 300 (the first blocking gas supply section 310 to the fourth blocking gas supply section 340) of the exemplary embodiment supplies the interior space 100a with the blocking gas (the first blocking gas to the fourth blocking gas) as-is without especially conducting preheating.

Moreover, the heating mechanism 500 as an example of a heating unit is, as shown in FIG. 3, provided below the rotating table 112 in the floor section 110. The heating mechanism 500 includes: a first heater 510 arranged below the loading body 113 attached onto the rotating table 112; a second heater 520 arranged outside of a peripheral edge of the first heater 510; a third heater 530 arranged outside of a peripheral edge of the second heater 520; and a reflective member 540 provided below the first heater 510 to the third heater 530 to reflect heat generated downward from the first heater 510 to the third heater 530 toward the rotating table 112 side. These first heater 510 to third heater 530 are configured with, for example, graphite (carbon), and are heaters of the self-heating type that evolves heat by itself by a current supplied from a not-shown power supply. Moreover, in the exemplary embodiment, the reflective member 540 is also configured with graphite (carbon).

It should be noted that, in the CVD device 1 of the exemplary embodiment, a purge gas constituted by argon (Ar) gas is supplied toward the interior space 100a from beneath the rotating table 112 and the heating mechanism 500, to thereby suppress flow of the raw-material gas or the like into the heating mechanism 500 side from the interior space 100a via a gap between the fixing section 111 and the rotating table 112. It should be noted that the reason why argon gas is used as the purge gas is that, in a case where hydrogen gas is used as the purge gas, a heating efficiency of the substrate S by the heating mechanism 500 is reduced.

Further, the cooling mechanism 700 as an example of a cooling unit includes, as shown in FIG. 1, a first water supply and drainage section 710 that carries out supply and drainage of cooling water to and from the first dividing member 171, a second water supply and drainage section 720 that carries out supply and drainage of cooling water to and from the second dividing member 172 and a third water supply and drainage section 730 that carries out supply and drainage of cooling water to and from the third dividing member 173. It should be noted that, in the exemplary embodiment, with respect to the ceiling 120 attached in a state where stainless steel is exposed to the interior space 100a in the same way as these first dividing member 171 to third dividing member 173, cooling by use of the cooling mechanism 700 is not performed. However, with respect to the first outer wall 132 in the first side wall 130, the second outer wall 142 in the second side wall 140, the third outer wall 152 in the third side wall 150, the fourth outer wall 162 in the fourth side wall 160 and the ceiling 120, cooling by use of the cooling mechanism 700 may be performed in the same manner as these first dividing member 171 to third dividing member 173.

Then, the reaction chamber 10 further includes: a first blocking gas diffusing member 181 that is provided on the downstream side (the upper side) of the first region A1 in the Z-direction to face the ceiling 120, and lowers the first blocking gas, which has been supplied from the first blocking gas supply section 310 to the inside of the first region A1 along the -Z-direction, while diffusing thereof in the horizontal direction (the X-direction and the Y-direction); a second blocking gas diffusing member 182 that is provided on the downstream side of the second region A2 in the Z-direction to face the ceiling 120, and lowers the second blocking gas, which has been supplied from the second blocking gas supply section 320 to the inside of the second region A2 along the -Z-direction, while diffusing thereof in the horizontal direction; a third blocking gas diffusing member 183 that is provided on the downstream side of the third region A3 in the Z-direction to face the ceiling 120, and lowers the third blocking gas, which has been supplied from the third blocking gas supply section 330 to the inside of the third region A3 along the -Z-direction, while diffusing thereof in the horizontal direction; and a fourth blocking gas diffusing member 184 that is provided on the downstream side of the fourth region A4 in the Z-direction to face the ceiling 120, and lowers the fourth blocking gas, which has been supplied from the fourth blocking gas supply section 340 to the inside of the fourth region A4 along the -Z-direction, while diffusing thereof in the horizontal direction. Here, the first blocking gas diffusing member 181 is configured by stacking plural (in this example, five) rectangular-shaped plate members, in each of which plural holes are formed along the XY plane, in the Z-direction. Moreover, the second blocking gas diffusing member 182 to the fourth blocking gas diffusing member 184 have configurations in common with that of the first blocking gas diffusing member 181.

### [Configuration of First Dividing Member]

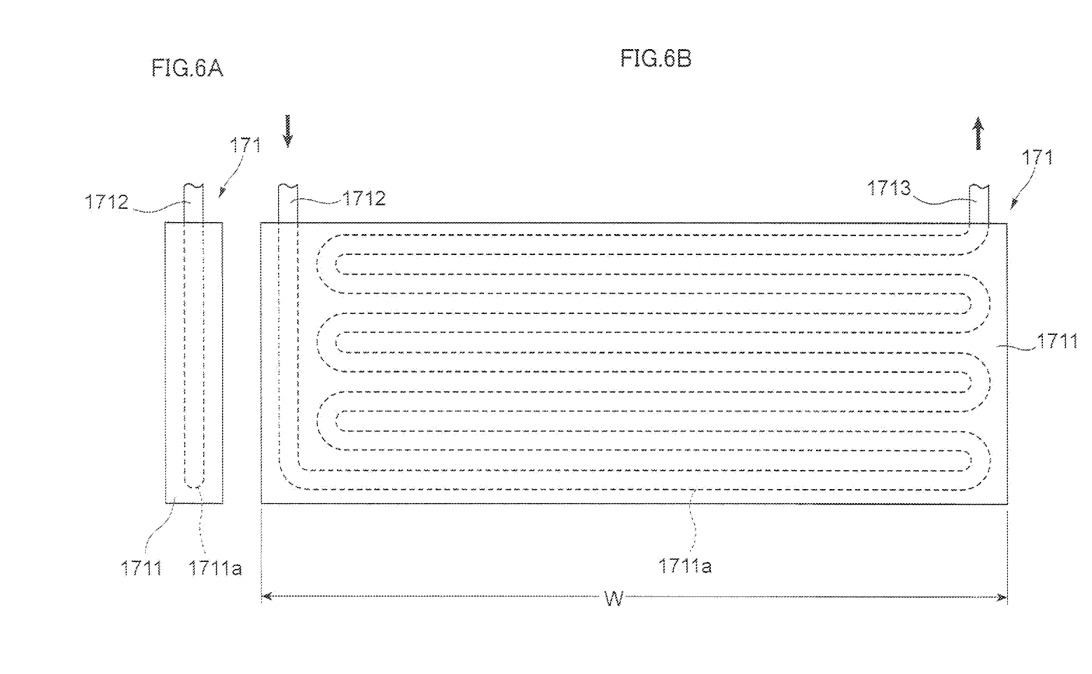

FIG. 6 is a diagram for illustrating a configuration of the first dividing member 171 provided in the container chamber 100. Here, FIG. 6A is a diagram in which the first dividing member 171 is viewed from the Y-direction, and FIG. 6B is a diagram in which the first dividing member 171 is viewed from the X-direction. It should be noted that, though not described in detail, the second dividing member 172 and the third dividing member 173 have configurations in common with the first dividing member 171.

The first dividing member 171 shows an outer appearance of a rectangular parallelepiped shape, and includes: a plate-like member 1711 inside of which a hollow internal piping 1711a is formed; a water supply tube 1712 that is attached to one end of the internal piping 1711a and serves as an inlet of water to the internal piping 1711a; and a water drainage tube 1713 that is attached to the other end of the internal piping 1711a and serves as an outlet of water from the internal piping 1711a. It should be noted that each of the plate-like member 1711, the water supply tube 1712 and the water drainage tube 1713 that constitute the first dividing member 171 is configured with stainless steel. In the first dividing member 171, both of the water supply tube 1712 and the water drainage tube 1713 are attached to a surface, of the plate-like member 1711, that faces the ceiling 120 (refer to FIG. 3 or the like) when the CVD device 1 is configured. Then, these water supply tube 1712 and water drainage tube 1713 protrude to the outside of the interior space 100a through not-shown holes provided in the ceiling 120, to be thereby connected to the first water supply and drainage section 710 (refer to FIG. 1) through not-shown external pipings. It should be noted that, the length in the Y-direction of the plate-like member 1711 constituting the first dividing member 171 is set at the above-described interior width W. Accordingly, when the CVD device 1 is configured, an end face of the plate-like member 1711 in the first dividing member 171 on the upstream side in the Y-direction is in contact with the first side wall 130, whereas, an end face of the plate-like member 1711 in the first dividing member 171 on the downstream side in the Y-direction is in contact with the second side wall 140.

### [Dimension of Reaction Container]

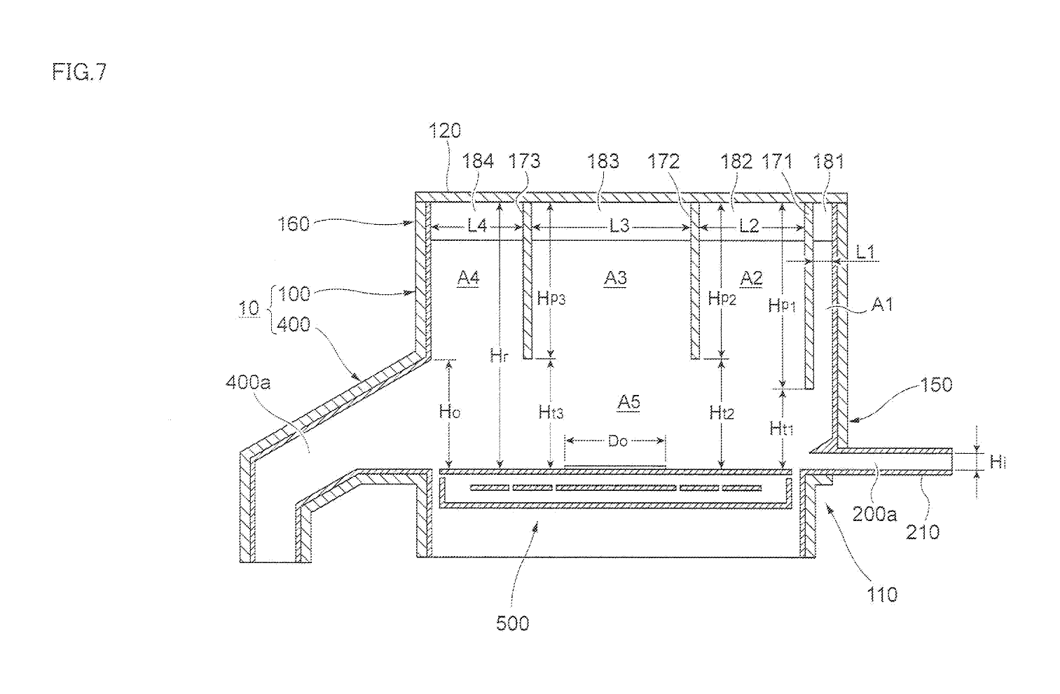

FIG. 7 is a diagram for illustrating various dimensions in the reaction container 10.

First, in the container chamber 100 of the reaction container 10 (the interior space 100a), the distance from the floor section 110 to the ceiling 120 in the Z-direction is assumed to be an interior height Hr. Moreover, it is assumed that the length of the first dividing member 171 in the Z-direction is a first dividing height Hp1, the length of the second dividing member 172 in the Z-direction is a second dividing height Hp2 and the length of the third dividing member 173 in the Z-direction is a third dividing height Hp3. Further, it is assumed that the distance from the floor section 110 to the lower end of the first dividing member 171 is a first space height Ht1, the distance from the floor section 110 to the lower end of the second dividing member 172 is a second space height Ht2 and the distance from the floor section 110 to the lower end of the third dividing member 173 is a third space height Ht3. At this time, Hr=Hp1+Ht1=Hp2+Ht2=Hp3+Ht3 holds.

Moreover, the distance in the Z-direction in an outlet of the supply space 200a (a communicating portion with the interior space 100a) is assumed to be a supply port height Hi, and the distance in the Z-direction in an inlet of the discharge space 400a (a communicating portion with the interior space 100a) is assumed to be a discharge port height Ho.

Further, it is assumed that the length of the first region A1 in the X-direction is a first region length L1, the length of the second region A2 in the X-direction is a second region length L2, the length of the third region A3 in the X-direction is a third region length L3 and the length of the fourth region A4 in the X-direction is a fourth region length L4.

It should be noted that the length of each of the first region A1 to the fifth region A5 in the Y-direction is, as described above, the common interior width W (refer to FIG. 5).

In the exemplary embodiment, the first dividing height Hp1, the second dividing height Hp2 and the third dividing height Hp3 have the relation specified by the expression Hp1>Hp2=Hp3. Then, the interior height Hr and each of these first dividing height Hp1 to third dividing height Hp3 have the relation specified by the expression Hp1≧Hr/2, Hp2≧Hr/2 and Hp3≧Hr/2. Here, since each of the interior height Hr and the first dividing height Hp1 to the third dividing height Hp3 regards the ceiling 120 as an upper end reference position, the lower end of each of the first dividing member 171 to the third dividing member 173 is positioned closer to the floor section 110 than the ceiling 120.

Moreover, the supply port height Hi, the first interior height Ht1 to the third interior height Ht3 and the discharge port height Ho have the relation specified by the expression Hi<Ht1<Ht2=Ht3=Ho. Here, since each of the supply port height Hi, the first interior height Ht1 to the third interior height Ht3 and the discharge port height Ho regards the floor section 110 as a lower end reference position, the upper end of the discharge port exists at a position higher than the upper end of the supply port.

Further, the first region length L1 to the fourth region length L4 have the relation specified by the expression L1<L4<L2<L3. Then, the first region length L1 is, as compared with the second region length L2 to the fourth region length L4, for example, set to one quarter or less.

Still further, the loading body outer diameter Do of the loading body 113 to load the substrate S and the third region length L3 of the third region A3 positioned immediately above the loading body 113 have the relation specified by the expression Do<L3. Here, since the loading body outer diameter Do and the substrate diameter Ds of the substrate S have the relation specified by the expression Ds<Do (refer to FIG. 2), the third region length L3 and the substrate diameter Ds have the relation specified by the expression Ds<L3.

### <Film-Forming Operation by Use of CVD Device>

Next, description will be given of a film-forming operation by use of the CVD device 1 of the exemplary embodiment.

First, the substrate S, whose film-formation surface faces outward, is loaded on the recessed portion 113a of the loading body 113. Next, on the rotating table 112 (the receiving portion 112a) of the floor section 110 in the CVD device 1, the loading body 113 on which the substrate S is loaded is set.

Subsequently, by use of the used gas discharge section 600, degassing of the interior space 100a, the supply space 200a and the discharge space 400a is performed, and the carrier gas is supplied to the interior space 100a from the supply space 200a by use of the raw-material gas supply section 200, as well as the blocking gas is supplied to the interior space 100a by use of the blocking gas supply section 300. This replaces the atmosphere in the interior space 100a, the supply space 200a and the discharge space 400a with the hydrogen gas (the blocking gas and the carrier gas), and reduces the pressure from a normal pressure to a predetermined pressure (in this example, 200 hPa). At this time, a supply amount of the first blocking gas, the second blocking gas, the third blocking gas and the fourth blocking gas from the first blocking gas supply section 310, the second blocking gas supply section 320, the third blocking gas supply section 330 and the fourth blocking gas supply section 340, which constitute the blocking gas supply section 300, respectively, are selected from the range of, for example, 10 L (liter)/min to 30 L/min. The supply amount of the carrier gas by the raw-material gas supply section 200 is selected from the range of, for example, 1 L/min to 100 L/min.

Then, by use of the rotational driving section 800, the rotating table 112 of the floor section 110 is driven. With this, the loading body 113 set on the rotating table 112 and the substrate S loaded on the loading body 113 are rotated in the direction of arrow A. At this time, the rotation speed of the rotating table 112 (the substrate S) is 10 rpm to 20 rpm.

Moreover, cooling of the flow-adjusting section 170 by use of the cooling mechanism 700 is started. To describe more specifically, water supply and drainage to and from the first dividing member 171 by the first water supply and drainage section 710, water supply and drainage to and from the second dividing member 172 by the second water supply and drainage section 720 and water supply and drainage to and from the third dividing member 173 by the third water supply and drainage section 730 are started.

After cooling of the flow-adjusting section 170 by use of the cooling mechanism 700 is started, electrical supply to the first heater 510 to the third heater 530, which constitute the heating mechanism 500, is started to cause each the first heater 510 to the third heater 530 to evolve heat, and thereby the substrate S is heated via the rotating table 112 and the loading body 113. Here, electrical supply to the first heater 510 to the third heater 530 is configured to be individually controlled, and heating control is conducted so that the temperature of the substrate S reaches a film-formation temperature selected from the range of 1500° C. to 1800° C. (in this example, 1600° C.). Moreover, with starting of heating operation by the heating mechanism 500, supply of the argon gas as the purge gas is started. Then, after the substrate S is heated to the film-formation temperature, the heating mechanism 500 changes the heating control to keep the substrate S at the film-formation temperature.

After the substrate S is heated to the film-formation temperature by the heating mechanism 500, while continuously performing supply of the blocking gas to the interior space 100a by the blocking gas supply section 300 under the above-described conditions, supply of the raw-material gas to the interior space 100a from the raw-material gas supply section 200 via the supply duct 210 (the supply space 200a) is started. In other words, the raw-material gas supply section 200 starts to supply the silicon-containing gas (in this example, monosilane gas) and the carbon-containing gas (in this example, propane gas) in addition to the carrier gas. At this time, it is preferable to start supplying the silicon-containing gas and the carbon-containing gas simultaneously. Here, “simultaneous supply” does not require perfectly the same time, but is meant to be within a range of a few seconds.

At this time, the supply amount of the silane gas is selected from a range of, for example, 50 sccm to 300 sccm, and the supply amount of the propane gas is selected from a range of, for example, 12 sccm to 200 sccm. However, the supply amounts of the silane gas and the propane gas are determined so that the concentration ratio of carbon and silicon, namely, C/Si, falls within the range of 0.8 to 2.0. Moreover, the supply amount of the carrier gas at this time is selected from the range of, for example, 1 L/min to 100 L/min, as described above.

Then, the raw-material gas that has been supplied from the raw-material gas supply section 200 along the X-direction is brought into the state of being spread in the Y-direction in the supply duct 210, and thereafter, brought into the interior space 100a along the X-direction.

It should be noted that, in this example, the monosilane gas and the propane gas are used as the silicon-containing gas and the carbon-containing gas, respectively; however, there is no limitation to these gases. As the silicon-containing gas, for example, disilane (Si₂H₂) gas or the like may be used. Moreover, as the carbon-containing gas, ethylene (C₂H₂) gas, ethane (C₂H₂) gas or the like may be used. Further, as the silicon-containing gas, dichlorosilane gas, trichlorosilane gas or the like containing Cl may be used. Still further, in this example, the hydrogen (H₂) gas is singly used as the carrier gas; however, it may be acceptable to use the hydrogen (H₂) gas containing hydrochloric acid (HCl) gas.

The raw-material gas brought into the interior space 100a by the raw-material gas supply section 200 reaches the periphery of the substrate S rotating in the direction of arrow A in a state of being guided in the X-direction and prevented from floating in the Z-direction (upward) by the blocking gas. Of the raw-material gas having reached the periphery of the substrate S, the monosilane gas is decomposed into silicon and hydrogen by heat transmitted via the substrate S or the like, and the propane gas is decomposed into carbon and hydrogen by heat transmitted via the substrate S or the like. Then, silicon and carbon obtained by thermal decomposition are deposited in order on the surface of the substrate S while keeping regularity, and accordingly, on the substrate S, a 4H-SiC film is epitaxially grown.

Then, the raw-material gas (including the one having already been reacted) and the blocking gas moving in the X-direction in the interior space 100a are further moved in the X-direction by the degassing operation of the used gas discharge section 600, brought into the discharge space 400a provided to the discharge duct 400 from the interior space 100a, and further, discharged to the outside of the reaction container 10.

Then, when formation of the 4H-SiC epitaxial film having a thickness required as an SiC epitaxial wafer is completed on the substrate S, the raw-material gas supply section 200 stops supply of the raw-material gas to the interior space 100a. Moreover, the heating mechanism 500 stops heating of the substrate S, on which the 4H-SiC epitaxial film is laminated, and the rotational driving section 800 stops driving of the rotating table 112 (rotation of the substrate S). Further, in the state where the substrate S is sufficiently cooled, supply of the blocking gas, supply of the purge gas by use of the blocking gas supply section 300 and cooling of the flow-adjusting section 170 by use of the cooling mechanism 700 are stopped, to thereby complete a series of film-forming operations. Then, after the degassing operation by the used gas discharge section 600 is stopped and thereby the interior space 100a is returned to the normal pressure, the substrate S on which the 4H-SiC epitaxial film is laminated, namely, the SiC epitaxial wafer is taken out of the reaction container 10 together with the loading body 113, and the SiC epitaxial wafer is detached from the loading body 113.

### [Flows of Raw-Material Gas and Blocking Gas in Container Chamber]

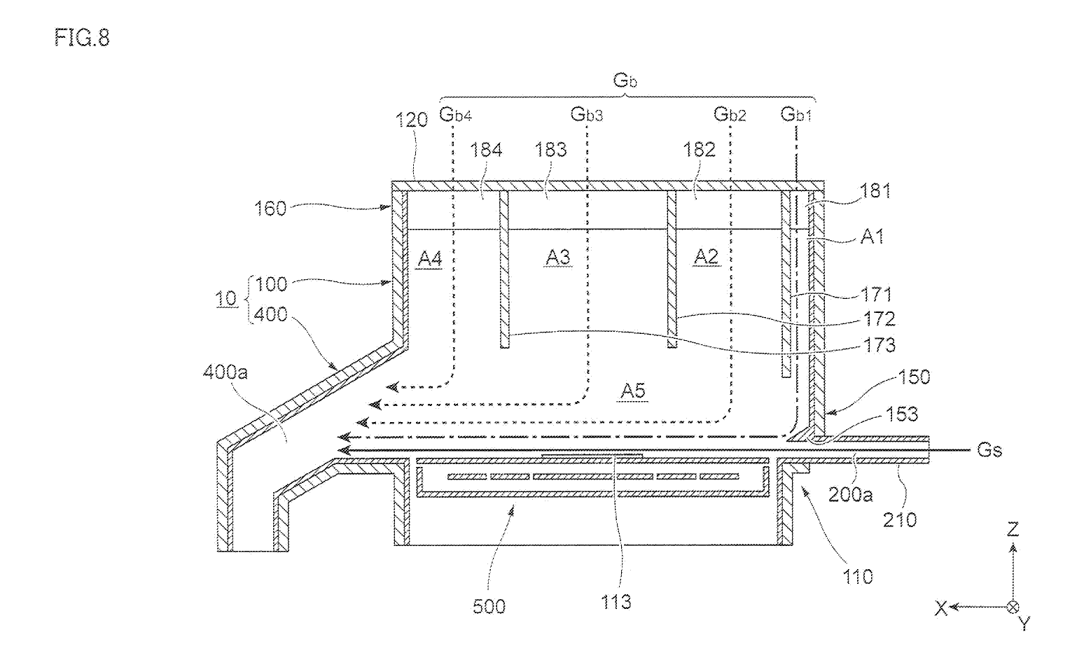

FIG. 8 is a diagram schematically showing the flow of the raw-material gas and the blocking gas in the container chamber 100.

First, the raw-material gas Gs that has been supplied from the raw-material gas supply section 200 (refer to FIG. 1) to the interior space 100a via the supply space 200a is carried into the fifth region A5 from a portion below the first region A1. Then, the raw-material gas Gs carried into the fifth region A5 is moved along the X-direction toward the loading body 113 (the substrate S) by a propulsive force imparted by the raw-material gas supply section 200 and an absorptive force generated by the degassing operation of the used gas discharge section 600 (refer to FIG. 1) while facing the floor section 110.

Moreover, the first blocking gas Gb1 supplied from the first blocking gas supply section 310 (refer to FIG. 1) to the first region A1 is diffused within the range of the first region A1 in the X-direction and the Y-direction by the first blocking gas diffusion member 181, while lowering along the -Z-direction. The first blocking gas Gb1 having passed through the first blocking gas diffusion member 181 is further lowered along the -Z-direction within the first region A1, and is carried from the first region A1 into the fifth region A5. Here, below the first region A1, the protruding member 153 provided in the third side wall 150 is positioned. For this reason, the first blocking gas Gb1 carried into the fifth region A5 changes the moving direction thereof from the direction along the -Z-direction to the direction along the X-direction by being guided by the inclined surface provided to the protruding member 153 and pulled by the absorptive force of the used gas discharge section 600 (refer to FIG. 1). While changing the moving direction from the -Z-direction to the X-direction, the first blocking gas Gb1 bumps against the raw-material gas Gs moving in the fifth region A5 along the X-direction. Then, the first blocking gas Gb1, whose moving direction has been changed into the X-direction, moves along the X-direction toward a portion of the fifth region A5 positioned below the second region A2, together with the raw-material gas Gs. At this time, the first blocking gas Gb1 moving toward the X-direction is brought into a state of covering an upper portion of the raw-material gas Gs that similarly moves toward the X-direction, to thereby suppress floating upward (the first region A1 side) of the raw-material gas Gs moving toward the X-direction. As a result, it is possible to prevent the raw-material gas Gs from entering the first region A1, and by extension, from reaching a portion, of the ceiling 120, which is an upper end of the first region A1.

Here, through the supply space 200a, the raw-material gas Gs having moved to the portion, of the fifth region A5 in the interior space 100a, below the first region A1 is to expand in a stroke because the pressure in the interior space 100a is lower than the pressure in the supply space 200a. Moreover, the raw-material gas Gs, which has moved from the portion, of the fifth region A5, below the first region A1 to the portion below the second region A2, expands by receiving heat by the heating mechanism 500 via the rotating table 112 and nearly floats from the lower side to the upper side. At this time, the first blocking gas Gb1 moving along the X-direction together with the raw-material gas Gs suppresses floating upward of the raw-material gas Gs.

Moreover, the second blocking gas Gb2 supplied from the second blocking gas supply section 320 (refer to FIG. 1) to the second region A2 is diffused within the range of the second region A2 in the X-direction and the Y-direction by the second blocking gas diffusion member 182, while lowering along the -Z-direction. The second blocking gas Gb2 having passed through the second blocking gas diffusion member 182 is further lowered along the -Z-direction within the second region A2, and is carried from the second region A2 into the fifth region A5. Accordingly, the second blocking gas Gb2 carried from the second region A2 into the fifth region A5 along the -Z-direction results in pressing the raw-material gas Gs and the first blocking gas Gb1, which exist in a portion, of the fifth region A5, below the second region A2, from above. Consequently, together with the first blocking gas Gb1, the second blocking gas Gb2 carried into the fifth region A5 along the -Z-direction suppresses floating upward of the raw-material gas Gs moving along the X-direction. As a result, it is possible to prevent the raw-material gas Gs from entering the second region A2, and by extension, from reaching a portion, of the ceiling 120, which is an upper end of the second region A2.

It should be noted that the second blocking gas Gb2 having moved along the -Z-direction changes the moving direction thereof from the direction along the -Z-direction to the direction along the X-direction by being pulled by the absorptive force of the used gas discharge section 600 (refer to FIG. 1). Then, the second blocking gas Gb2, whose moving direction has been changed into the X-direction, moves along the X-direction toward a portion, of the fifth region A5, positioned below the third region A3, together with the raw-material gas Gs and the first blocking gas Gb1.

The raw-material gas Gs, which has moved from the portion, of the fifth region A5, below the second region A2 to the portion below the third region A3, expands by receiving heat by the heating mechanism 500 via the rotating table 112, the loading body 113 and the substrate S and nearly floats from the lower side to the upper side. At this time, the first blocking gas Gb1 and the second blocking gas Gb2 moving along the X-direction together with the raw-material gas Gs suppress floating upward of the raw-material gas Gs.

Moreover, the third blocking gas Gb3 supplied from the third blocking gas supply section 330 (refer to FIG. 1) to the third region A3 is diffused within the range of the third region A3 in the X-direction and the Y-direction by the third blocking gas diffusion member 183, while lowering along the -Z-direction. The third blocking gas Gb3 having passed through the third blocking gas diffusion member 183 is further lowered along the -Z-direction within the third region A3, and is carried from the third region A3 into the fifth region A5. Accordingly, the third blocking gas Gb3 carried from the third region A3 into the fifth region A5 along the -Z-direction results in pressing the raw-material gas Gs, the first blocking gas Gb1 and the second blocking gas Gb2 which exist in a portion, of the fifth region A5, below the third region A3, from above. Consequently, together with the first blocking gas Gb1 and the second blocking gas Gb2, the third blocking gas Gb3 carried along the -Z-direction suppresses floating upward (the third region A3) of the raw-material gas Gs moving along the X-direction. As a result, it is possible to prevent the raw-material gas Gs from entering the third region A3, and by extension, from reaching a portion, of the ceiling 120, which is an upper end of the third region A3.

It should be noted that the third blocking gas Gb3 having moved along the -Z-direction changes the moving direction thereof from the direction along the -Z-direction to the direction along the X-direction by being pulled by the absorptive force of the used gas discharge section 600 (refer to FIG. 1). Then, the third blocking gas Gb3, whose moving direction has been changed into the X-direction, moves along the X-direction toward a portion, of the fifth region A5, positioned below the fourth region A4, together with the raw-material gas Gs, the first blocking gas Gb1 and the second blocking gas Gb2.

Here, at a portion, of the fifth region A5, positioned below the third region A3, as described above, the loading body 113 and the substrate S loaded on the loading body 113 are arranged. Then, at this portion, the raw-material gas Gs is pressed against the substrate S side by use of the first blocking gas Gb1 to the third blocking gas Gb3, and accordingly, most of the raw-material gas Gs exists around the substrate S. At this time, the substrate S has been heated to the film-forming temperature by the heating mechanism 500 (refer to FIG. 3), and thereby, of the raw-material gas Gs existing around the substrate S, the monosilane gas and the propane gas are subjected to thermal decomposition with heating via the substrate S and the like, and on the substrate S, the 4H-SiC single crystal by Si and C obtained by the thermal decomposition is epitaxially grown. However, all of Si and C obtained by the thermal decomposition are not used for the epitaxial growth on the substrate S, and a part thereof moves along the X-direction together with the first blocking gas Gb1 to the third blocking gas Gb3. Moreover, the hydrogen gas (reacted gas) obtained by thermal decomposition of the monosilane gas and the propane gas also moves along the X-direction together with the first blocking gas Gb1 to the third blocking gas Gb3. Further, part of the monosilane gas and part of the propane gas are not subjected to the thermal decomposition around the substrate S, and move along the X-direction as they are.

The raw-material gas Gs (including the unreacted gas and the reacted gas) having moved to a portion below the fourth region A4 from the portion below the third region A3, of the fifth region A5, expands upon receiving heat from the heating mechanism 500 via the rotating table 112, and nearly floats from the lower side toward the upper side. At this time, the first blocking gas Gb1 to the third blocking gas Gb3 moving along the X-direction, together with the raw-material gas Gs, suppress floating upward of the raw-material gas Gs.

Moreover, the fourth blocking gas Gb4 supplied from the fourth blocking gas supply section 340 (refer to FIG. 1) to the fourth region A4 is diffused in the X-direction and the Y-direction within the range of the fourth region A4 by the fourth blocking gas diffusion member 184 while lowering along the -Z-direction. The fourth blocking gas Gb4 having passed through the fourth blocking gas diffusion member 184 is further lowered along the -Z-direction within the fourth region A4, and is carried from the fourth region A4 into the fifth region A5. Accordingly, the fourth blocking gas Gb4 carried from the fourth region A4 into the fifth region A5 along the -Z-direction results in pressing the raw-material gas Gs and the first blocking gas Gb1 to the third blocking gas Gb3 which exist in a portion, of the fifth region A5, below the fourth region A4, from above. Consequently, together with the first blocking gas Gb1 to the third blocking gas Gb3, the fourth blocking gas Gb4 carried along the -Z-direction suppresses floating upward (the fourth region A4) of the raw-material gas Gs moving along the X-direction. As a result, it is possible to prevent the raw-material gas Gs from entering the fourth region A4, and by extension, from reaching a portion, of the ceiling 120, which is an upper end of the fourth region A4.

It should be noted that the fourth blocking gas Gb4 having moved along the -Z-direction changes the moving direction thereof from the direction along the -Z-direction to the direction along the X-direction by being pulled by the absorptive force of the used gas discharge section 600 (refer to FIG. 1). Then, the fourth blocking gas Gb4, whose moving direction has been changed into the X-direction, moves along the X-direction toward a communication portion between the fifth region A5 and the discharge space 400a, together with the raw-material gas Gs and the first blocking gas Gb1 to the third blocking gas Gb3. Then, the raw-material gas Gs and the first blocking gas Gb1 to the fourth blocking gas Gb4 are discharged to the outside by the used gas discharge section 600 via the discharge space 400a.

During this time, the first water supply and drainage section 710, the second water supply and drainage section 720 and the third water supply and drainage section 730 that constitute the cooling mechanism 700 carry out supply and drainage of the cooling water to and from the first dividing member 171, the second dividing member 172 and the third dividing member 173 that constitute the flow-adjusting section 170, respectively. This maintains the temperatures of the first dividing member 171, the second dividing member 172 and the third dividing member 173, including lower end portions thereof, to 200° C. or lower. Moreover, since the ceiling 120 is apart from the heating mechanism 500, the blocking gas is supplied to the fifth region A5 via the first region A1 to the fourth region A4 and the first dividing member 171 to the third dividing member 173 are cooled, the ceiling 120 is maintained at the temperature of 50° C. or lower, even though the ceiling 120 is not directly cooled.

In this manner, in the exemplary embodiment, the first blocking gas Gb1 and the second blocking gas Gb2 play a role in guiding the raw-material gas Gs along the X-direction toward the substrate S side, the third blocking gas Gb3 plays a role in pressing the raw-material gas Gs passing through the substrate S along the X-direction against the substrate S from above, and the fourth blocking gas Gb4 plays a role in guiding the raw-material gas Gs having passed through the substrate S toward the discharge duct 400 side along the X-direction.

Here, it is assumed that the moving speed of the first blocking gas Gb1 carried from the first region A1 to the fifth region A5 is a first blocking gas flow rate Vb1, the moving speed of the second blocking gas Gb2 carried from the second region A2 to the fifth region A5 is a second blocking gas flow rate Vb2, the moving speed of the third blocking gas Gb3 carried from the third region A3 to the fifth region A5 is a third blocking gas flow rate Vb3, and the moving speed of the fourth blocking gas Gb4 carried from the fourth region A4 to the fifth region A5 is a fourth blocking gas flow rate Vb4. If it is assumed that the supply amount of each of the first blocking gas Gb1 to the fourth blocking gas Gb4 is, for example, 10 L (liter)/min, each flow rate is determined by the area of each of the first region A1 to the fourth region A4 on the XY plane. In the exemplary embodiment, as described above, since the lengths of the first region A1 to the fourth region A4 in the Y-direction is the interior width W and is constant, variety in the area is determined by the lengths of these first region A1 to fourth region A4 in the X-direction. Then, in the exemplary embodiment, as described above, the first region length L1, the second region length L2, the third region length L3 and the fourth region length L4, which are the lengths of the first region A1 to the fourth region A4 in the X-direction, respectively, have the relation specified by the expression L1<L4<L2<L3. Accordingly, the areas on the XY plane have the relation specified by the expression A1<A4<A2<A3, and the flow rates result in having the relation specified by the expression Vb3<Vb2<Vb4<Vb1.

In the CVD device 1 of the exemplary embodiment, the stainless steel constituting the first dividing member 171 to the third dividing member 173 or the ceiling 120 is exposed to the interior space 100a in which the raw-material gas Gs containing the silane gas or the propane gas exists. Then, in the case where carbon obtained by thermal decomposition of the propane gas contained in the raw-material gas Gs arrives at the first dividing member 171 to the third dividing member 173 or the ceiling 120, there is a possibility that a phenomenon called carburization, in which carbon enters into the first dividing member 171 to the third dividing member 173 or the ceiling 120, occurs, and as a result, the first dividing member 171 to the third dividing member 173 or the ceiling 120 become brittle. It should be noted that the present inventors have confirmed that there are some cases in which the carbonized deterioration occurs when members configured with stainless steel are similarly heated to 350° C. or higher in CVD devices in other modes.

Accordingly, in the CVD device 1 of the exemplary embodiment, during the film formation, the first dividing member 171 to the third dividing member 173 that constitute the above-described flow-adjusting section 170 were configured to be cooled to 300° C. or lower (in this example, 200° C. or lower) by use of the cooling mechanism 700 (the first water supply and drainage section 710 to the third water supply and drainage section 730). Moreover, by directly cooling the first dividing member 171 to the third dividing member 173 to 300° C. or lower by the cooling mechanism 700, the ceiling 120, to which these first dividing member 171 to third dividing member 173 were attached, was also configured to be indirectly cooled to 300° C. or lower (in this example, 50° C. or lower). This makes it possible to hardly cause carburization of stainless steel, and accordingly, deterioration of the first dividing member 171 to the third dividing member 173 or the ceiling 120 by carburization can be suppressed.

Moreover, in the exemplary embodiment, by supplying the blocking gas by use of the blocking gas supply section 300, the raw-material gas Gs that flowed below the blocking gas and was heated by the heating mechanism 500 was configured to be less likely to come close to the upper side, namely, the first dividing member 171 to the third dividing member 173 or the ceiling 120. This makes it possible to cause the propane gas to hardly arrive at the first dividing member 171 to the third dividing member 173 or the ceiling 120, and accordingly, it becomes possible to further suppress deterioration of the first dividing member 171 to the third dividing member 173 or the ceiling 120 due to carburization.

As a result, in the CVD device 1 of the exemplary embodiment, life extension of the reaction container 10 including the container chamber 100 is able to be promoted.

Moreover, in the exemplary embodiment, by providing the flow-adjusting section 170 constituted by the first dividing member 171 to the third dividing member 173 in the interior space 100a in the container chamber 100 that contains the substrate S, the interior space 100a was configured to be divided into the first region A1 to the fifth region A5. Then, in the fifth region A5 where the substrate S was arranged, the raw-material gas Gs was configured to be supplied along the X-direction from the lateral side of the fifth region A5, and the first blocking gas Gb1 to the fourth blocking gas Gb4 were configured to be supplied along the -Z-direction, which is headed for the fifth region A5, from the first region A1 to the fourth region A4, respectively. Consequently, it is possible to suppress movement of the raw-material gas Gs toward the upper side in the interior space 100a, and to prevent the raw-material gas Gs from reaching the ceiling 120 positioned on the upper side of the interior space 100a. Consequently, it is possible to suppress adhesion of the reaction products to the ceiling 120 due to reaction of the raw-material gas Gs in the vicinity of the ceiling 120. Therefore, it is possible to make an accident that the reaction products from the ceiling 120 falls onto the substrate S less likely to occur.

Further, in the exemplary embodiment, as described above, during the film formation, the first dividing member 171 to the third dividing member 173 that constitute the above-described flow-adjusting section 170 were configured to be cooled by use of the cooling mechanism 700 (the first water supply and drainage section 710 to the third water supply and drainage section 730). Since these first dividing member 171 to the third dividing member 173 are arranged to be extended to a side closer to the substrate S (the heating mechanism 500) than the above-described ceiling 120, the first dividing member 171 to the third dividing member 173 are likely to be heated by the heating mechanism 500, and the raw-material gas Gs is more likely to arrive at the first dividing member 171 to the third dividing member 173 than at the ceiling 120. For this reason, it can be said that the reaction products due to the raw-material gas Gs are in a state of easily adhering to, in particular, the lower end side of the first dividing member 171 to the third dividing member 173. However, in the exemplary embodiment, by cooling the flow-adjusting section 170 by use of the cooling mechanism 700, there is provided an environment in which, even on the lower end side of the first dividing member 171 to the third dividing member 173, thermal decomposition of the raw-material gas Gs hardly occurs. It should be noted that, since thermal decomposition of the raw-material gas Gs used in the exemplary embodiment occurs at the temperature of 600° C. or higher, on the lower end side of the first dividing member 171 to the third dividing member 173, which is cooled to 300° C. or lower, thermal decomposition hardly occurs. Consequently, it becomes possible to suppress adherence of the reaction products to these first dividing member 171 to the third dividing member 173 positioned above the substrate S, and it is possible to cause the situation, in which the reaction products from the first dividing member 171 to the third dividing member 173 fall onto the substrate S, to be hardly generated.

Moreover, in the exemplary embodiment, the first dividing member 171 to the third dividing member 173, which were located above the interior space 100a, were configured to be arranged to avoid a location directly above the substrate S that is provided on the floor section 110. Since these first dividing member 171 to the third dividing member 173 are arranged to be extended to a side closer to the substrate S (the heating mechanism 500) than the above-described ceiling 120, the first dividing member 171 to the third dividing member 173 are likely to be heated by the heating mechanism 500, and the raw-material gas Gs is more likely to arrive at the first dividing member 171 to the third dividing member 173 than at the ceiling 120. For this reason, it can be said that the reaction products due to the raw-material gas Gs are in a state of easily adhering to, in particular, the lower end side of the first dividing member 171 to the third dividing member 173. However, in the exemplary embodiment, even in the provisional case where the reaction products adhere to the lower end side of these first dividing member 171 to third dividing member 173 and the adhered reaction products are peeled off from the first dividing member 171 to the third dividing member 173, the reaction products having been peeled off tend to fall, due to gravity, onto the location avoiding the film-formation surface on the substrate S. Particularly, in the case where film formation is carried out in an atmosphere with reduced pressure, as in the exemplary embodiment, the reaction products adhered to the lower end side of the first dividing member 171 to the third dividing member 173 are tend to fall in the perpendicular direction, namely, in the vertical direction. Therefore, it is possible to make a situation in which the reaction products from the first dividing member 171 to the third dividing member 173 fall onto the substrate S less likely to occur.

It should be noted that, though the side walls in the interior space 100a (the first inner wall 131 in the first side wall 130, the second inner wall 141 in the second side wall 140, the third inner wall 151 in the third side wall 150 and the fourth inner wall 161 in the fourth side wall 160) are in a state where the reaction products are likely to adhere thereto as compared to the ceiling 120, the reaction products adhered to these side walls do not peel off much during film formation, and in a stage after the film is formed, where the temperature in the chamber is lowered, the reaction products peel off due to a difference in thermal expansion between the side walls and the reaction products in many cases. Moreover, for example, in a case where the SiC epitaxial wafer is taken out of the CVD device 1 (the container chamber 100), there are some cases in which a member constituting the container chamber 100 (for example, the ceiling 120) is removed or opened and closed, and on that occasion, oscillations are generated in the container chamber 100, to thereby encourage peeling off and falling of the reaction products adhered to the side walls or the like with the oscillations. However, if it is supposed that the reaction products peeled off from the side walls are on the substrate S on this stage, there is no particular problem since the reaction products are not taken into the 4H-SiC film on the substrate S.

Particularly, in the exemplary embodiment, though the substrate S is rotated in the direction of arrow A (refer to FIG. 4) together with the rotating table 112 during the film formation, the first dividing member 171 to the third dividing member 173 are arranged to avoid the location directly above a rotation trail of the substrate S in rotating. By employing such a configuration, it is possible to suppress various kinds of non-uniformities in the film to be formed on the substrate S (non-uniformity in composition, non-uniformity in thickness, and the like), and to suppress falling of the reaction products onto the substrate S.

Here, in the exemplary embodiment, during the film formation, the first dividing member 171 to the third dividing member 173 that constitute the above-described flow-adjusting section 170 were configured to be cooled by use of the cooling mechanism 700 (the first water supply and drainage section 710 to the third water supply and drainage section 730). Consequently, there is provided an environment in which, even on the lower end side of the first dividing member 171 to the third dividing member 173, thermal decomposition of the raw-material gas Gs hardly occurs. Accordingly, it becomes possible to suppress adherence itself of the reaction products to these first dividing member 171 to third dividing member 173 positioned above the substrate S, and further, it is possible to cause the situation, in which the reaction products from the first dividing member 171 to the third dividing member 173 fall onto the substrate S, to be hardly generated.

On the other hand, in the exemplary embodiment, in the interior space 100a of the container chamber 100 that contains the substrate S, the raw-material gas Gs was configured to be supplied from the lateral side of the substrate S along the X-direction by use of the raw-material gas supply section 200, and the first blocking gas Gb1 was configured to be supplied in an obliquely downward direction following the X-direction to a position on the upstream side of the substrate S in the X-direction and on the downstream side of the raw-material gas supply section 200 (the supply duct 210) in the X-direction by use of the first blocking gas supply section 310. This causes the raw-material gas Gs to be pressed by the first blocking gas Gb1 on the upstream side of the substrate S in the X-direction, and accordingly, it is possible to suppress diffusion of the raw-material gas Gs before reaching the substrate S. For this reason, as compared to the case where the present configuration is not employed, it becomes possible to increase the proportion of the raw-material gas Gs that is decomposed on the substrate S and contributes to film formation on the substrate, and accordingly, efficiency of use of the raw-material gas Gs in the formation of the 4H-SiC film can be improved.

Moreover, in the exemplary embodiment, the second blocking gas Gb2 was configured to be supplied against the raw-material gas Gs and the first blocking gas Gb1 moving along the X-direction. This makes it possible to further suppress diffusion of the raw-material gas Gs before reaching the substrate S, and accordingly, efficiency of use of the raw-material gas Gs in the formation of the 4H-SiC film can be further improved.

Further, in the exemplary embodiment, the third blocking gas Gb3 was configured to be supplied along the -Z-direction against the raw-material gas Gs moving along the X-direction and the first blocking gas Gb1 and the second blocking gas Gb2. This makes it possible to suppress diffusion of the raw-material gas Gs that has reached the substrate S, and accordingly, efficiency of use of the raw-material gas Gs in the formation of the 4H-SiC film can be more improved.

Still further, in the exemplary embodiment, the fourth blocking gas Gb4 was configured to be supplied along the -Z-direction against the raw-material gas Gs moving along the X-direction and the first blocking gas Gb1 to the third blocking gas Gb3. This makes it possible to suppress accumulation of the raw-material gas Gs (including the reacted gas) that has passed above the substrate S in the interior space 100a.

Moreover, in the exemplary embodiment, a first dividing height Hp1 of the first dividing member 171, a second dividing height Hp2 of the second dividing member 172 and a third dividing height Hp3 of the third dividing member 173, which constitute the above-described flow-adjusting section 170, were set at half or more of the interior height Hr of the container chamber 100. Consequently, as compared to a case where the first dividing height Hp1, the second dividing height Hp2 and the third dividing height Hp3 were set at less than half of the interior height Hr, it is possible to reduce the probability that, in the interior space 100a, the raw-material gas Gs having entered into the first region A1 to the fourth region A4 from the fifth region A5 reaches the ceiling 120 positioned at an uppermost part of the first region A1 to the fourth region A5. Accordingly, it becomes possible to further suppress adhesion of the reaction products to the ceiling 120 and falling of the reaction products from the ceiling 120.

Here, in the exemplary embodiment, the discharge port height Ho connecting the interior space 100a and the discharge space 400a was set as the same height as the third space height Ht3 in the interior space 100a (the distance in the Z-direction from the floor section 110 up to the lower end of the third dividing member 173). Consequently, the first blocking gas Gb1 to the third blocking gas Gb3 and the raw-material gas Gs having passed directly below the third dividing member 173 in the fifth region A5 are likely to be guided to the discharge space 400a side and less likely to be accumulated in the interior space 100a. This makes it possible to prevent the raw-material gas Gs from entering into the fourth region A4 from the fifth region A5.

Further, in the exemplary embodiment, the second space height Ht2 (the distance in the Z-direction from the floor section 110 up to the lower end of the second dividing member 172) in the interior space 100a was set as the same height as the above-described third space height Ht3. This makes it possible to prevent the first blocking gas Gb1, the second blocking gas Gb2 and the raw-material gas Gs having passed directly below the second dividing member 172 in the fifth region A5 from entering into the third region A3 from the fifth region A5.

Still further, in the exemplary embodiment, the first space height Ht1 (the distance in the Z-direction from the floor section 110 up to the lower end of the first dividing member 171) in the interior space 100a was set lower than the above-described second space height Ht2. Consequently, it is possible to prevent the first blocking gas Gb1 and the raw-material gas Gs having passed directly below the first dividing member 171 in the fifth region A5 from entering into the second region A2 from the fifth region A5, and when the raw-material gas Gs, which has passed through the supply space 200a, enters into the fifth region A5, it is possible to improve the effect of suppressing floating upward of the raw-material gas Gs by the first blocking gas Gb1.

As a result, it is possible to improve yields of the SiC epitaxial wafer produced by use of the CVD device 1 of the exemplary embodiment.

It should be noted that, in the exemplary embodiment, description has been given by taking a case, in which the first dividing member 171 to the third dividing member 173 exposed to the interior space 100a or the ceiling 120 are configured with stainless steel, as an example; however, the present invention is not limited thereto. For example, a configuration in which the first side wall 130 is configured with the first outer wall 132 made of stainless steel and the first outer wall 132 is cooled by the cooling mechanism 700 may be employed. The same can be said about the second side wall 140, the third side wall 150 and the fourth side wall 160.

Moreover, in the exemplary embodiment, description was given by taking the case of epitaxially growing the 4H-SiC single crystal film on the substrate S configured with the SiC single crystal as an example; however, the present invention is not limited thereto, and design changes on the polytype of the substrate S and the SiC single crystal thin film may be adequately carried out.

Further, in the exemplary embodiment, the first dividing member 171 to the third dividing member 173 are cooled by the water cooling system; however, the present invention is not limited thereto, and selection may be adequately carried out from various kinds of cooling systems.

Still further, in the exemplary embodiment, a so-called sheet-fed type, in which the substrate S is contained in the container chamber 100 one by one, was employed; however, there is no limitation thereto, and a batch type, in which plural substrates S are contained for collective film formation, may be employed.

### REFERENCE SIGNS LIST

1 . . . CVD device
10 . . . Reaction container
100 . . . Container chamber
100a . . . Interior space
110 . . . Floor section
111 . . . Fixing section
112 . . . Rotating table
113 . . . Loading body
120 . . . Ceiling
130 . . . First side wall
140 . . . Second side wall
150 . . . Third side wall
160 . . . Fourth side wall
170 . . . Flow-adjusting section
171 . . . First dividing member
172 . . . Second dividing member
173 . . . Third dividing member
200 . . . Raw-material gas supply section
200a . . . Supply space
300 . . . Blocking gas supply section
310 . . . First blocking gas supply section
320 . . . Second blocking gas supply section
330 . . . Third blocking gas supply section
340 . . . Fourth blocking gas supply section
400 . . . Discharge duct
400a . . . Discharge space
500 . . . Heating mechanism
600 . . . Used gas discharge section
700 . . . Cooling mechanism
710 . . . First water supply and drainage section
720 . . . Second water supply and drainage section
730 . . . Third water supply and drainage section
800 . . . Rotational driving section
A1 . . . First region
A2 . . . Second region
A3 . . . Third region
A4 . . . Fourth region
A5 . . . Fifth region

1. A film-forming device comprising:
a container chamber that includes an interior space to which a stainless steel member configured with a material containing stainless steel is exposed, and contains a substrate onto which an SiC film is formed;
a raw-material gas supply unit that supplies the interior space with a raw-material gas containing a first raw-material gas that contains Si and serves as a raw material of the SiC film and a second raw-material gas that contains C and serves as a raw material of the SiC film;
a heating unit that heats the substrate contained in the interior space; and
a cooling unit that cools a region of the stainless steel member, which is exposed to the interior space and positioned above the heating unit, to 300° C. or lower.

2. The film-forming device according to claim 1, wherein
the raw-material gas supply unit supplies the interior space with the raw-material gas along a first direction heading toward the substrate from a lateral side of the substrate,
a blocking gas supply unit, which supplies the interior space with a blocking gas that suppresses upward movement of the raw-material gas along a second direction heading downward from above, is further included, and
the stainless steel member is provided on an upper side in the interior space to extend in the second direction and to intersect the first direction, and includes a dividing member that divides the upper side in the interior space into a plurality of regions.

3. The film-forming device according to claim 2, wherein the stainless steel member is provided above the substrate in the interior space, and further includes a ceiling member to which the dividing member is attached.

4. The film-forming device according to claim 3, wherein the cooling unit indirectly cools the ceiling member via the dividing member by directly cooling the dividing member.

5. The film-forming device according to claim 2, wherein, on the upper side of the interior space, the blocking gas supply unit supplies each of the plurality of regions, which is formed by dividing the interior space by the dividing member, with the blocking gas.

6. The film-forming device according to claim 2, wherein
a plurality of the dividing members are provided, and
the cooling unit cools the plurality of the dividing members individually.

7. The film-forming device according to claim 1, wherein the SiC film formed on the substrate includes a 4H—SiC structure.

8. The film-forming device according to claim 1, wherein the container chamber contains the substrate on a lower side of the interior space so that a film-formation surface faces upward.

9. The film-forming device according to claim 1, wherein the heating unit heats the substrate to a film-forming temperature selected from a range of 1500° C. to 1800° C.
